(19) United States
(12) Patent Application Publication
(10) Pub. No.: US 2026/0262414 A1
(43) Pub. Date: Sep. 3, 2026

(54) DISPLAY DEVICE AND MANUFACTURING METHOD THEREFOR

(71) Applicant: BOE TECHNOLOGY GROUP CO., LTD., Beijing (CN)

(72) Inventors: Haoran WANG, Beijing (CN); Chunyan XIE, Beijing (CN); Song ZHANG, Beijing (CN); Xuekai YANG, Beijing (CN)

(73) Assignee: BOE TECHNOLOGY GROUP CO., LTD., Beijing (CN)

(21) Appl. No.: 18/995,686

(22) PCT Filed: Mar. 1, 2023
(86) PCT No.: PCT/CN2023/078937

§ 371 Date: Jan. 16, 2025

(51) Int. Cl. H10K 59/80; H10K 59/12; H10K 102/00

(52) U.S. Cl. CPC H10K 59/872; H10K 59/1201; H10K 59/873; H10K 2102/311

(57) ABSTRACT

The display device comprises a main display area and a secondary display area at least partially arranged on the periphery of the main display area. The display device comprises a flexible display panel having a main display panel in the main display area and a secondary display panel in the secondary display area; a display surface of the secondary display panel is an inclined surface, and an extension plane thereof intersects with the side of the main display panel away from the secondary display panel to form a virtual vertex or a virtual straight line; and a ratio of a distance between the virtual vertex or the virtual straight line and a display surface of the main display panel to a distance between a center point of the main display panel and a boundary line is greater than or equal to 0.2 and less than or equal to 12.

### CROSS-REFERENCE TO RELATED APPLICATIONS

This disclosure is the U.S. national phase application of PCT Application No. PCT/CN2023/078937, filed Mar. 1, 2023, entitled “Display Device and Manufacturing Method therefor,” the content of which is incorporated herein by reference in its entirety for all purposes.

### TECHNICAL FIELD

The present disclosure relates to the field of display technology, and particularly, to a display device and a manufacturing method therefor.

### BACKGROUND

With the development of science and technology, conventional wearable mobile display devices, such as smartwatches, are becoming more and more like mobile phones in terms of functionality, and are used either independently or in conjunction with corresponding smartphones, and gain growing favor among consumers.

At present, the display devices are poor in operation efficiency.

It should be noted that the information disclosed in the Background is only used to enhance understanding of the background of the present disclosure, and therefore it may include information that does not constitute existing technology already known to those skilled in the art.

### SUMMARY

The present disclosure aims to overcome the shortcomings in the related art, and provides a display device and a manufacturing method therefor.

According to an aspect of the present disclosure, there is provided a display device having a main display area and a secondary display area at least partially surrounding a periphery of the main display area, the main display area being spaced apart from the secondary display area. The display device includes:
a flexible display panel, including:
a main display panel disposed in the main display area; and
a secondary display panel disposed in the secondary display area, wherein a display surface of the secondary display panel is configured as an inclined surface; an extension plane of the display surface of the secondary display panel converge at a side of the main display panel away from the secondary display panel to form a virtual vertex or a virtual straight line; and a ratio of a distance between the virtual vertex or the virtual straight line and a display surface of the main display panel to a distance between a center point and a boundary line of the main display panel is greater than or equal to 0.2 and less than or equal to 12.

In an exemplary embodiment of the present disclosure, the secondary display panel includes a first display portion and a second display portion connected to each other; the flexible display panel further includes:
a connection portion connected between the first display portion and the main display panel, the second display portion being spaced apart from the main display panel.

In an exemplary embodiment of the present disclosure, the connection portion is provided with a plurality of via holes; or
the connection portion includes at least two connection strips, an end of each connection strip being connected to the main display panel, and an opposite end of each connection strip being connected to the first display portion.

In an exemplary embodiment of the present disclosure, each connection strip is curved.

In an exemplary embodiment of the present disclosure, the plurality of via holes are arranged along a circular arc at equal rotation angles.

In an exemplary embodiment of the present disclosure, the secondary display panel has a disconnection portion, and the disconnection portion and the connection portion are disposed on two opposite sides of the main display panel.

In an exemplary embodiment of the present disclosure, the flexible display panel further includes:

a first binding portion connected to the main display panel, the first binding portion extending to the disconnection portion, and the first binding portion being provided with a plurality of binding pins.

In an exemplary embodiment of the present disclosure, the display device further includes:
a cover plate disposed on a display surface of the flexible display panel, wherein the cover plate includes:
a main plate disposed in the main display area; and
an edge plate disposed in the secondary display area, the edge plate being connected to a periphery of the main plate, and a surface of the edge plate close to the flexible display panel being attached to the display surface of the secondary display panel.

In an exemplary embodiment of the present disclosure, an angle between the surface of the edge plate close to the flexible display panel and a surface of the main plate close to the flexible display panel is greater than 900 and less than or equal to 179°.

In an exemplary embodiment of the present disclosure, on a first reference plane, a distance between an end of the edge plate close to the main plate and the main plate is greater than or equal to 0.017 mm, and the first reference plane is parallel to the display surface of the main display panel.

In an exemplary embodiment of the present disclosure, the cover plate further includes:
a connection plate connected between the main plate and the edge plate, the connection plate having a positive Gaussian curvature, and the connection portion being attached to the connection plate.

In an exemplary embodiment of the present disclosure, the display device further includes:
a first shielding portion disposed on a side of the cover plate close to the flexible display panel, and the first shielding portion being located between the main display area and the secondary display area.

In an exemplary embodiment of the present disclosure, the display device further includes:
a second shielding portion disposed on the side of the cover plate close to the flexible display panel, and second shielding portion being located on a side of the secondary display area away from the main display area.

In an exemplary embodiment of the present disclosure, the display device further includes:
a third shielding portion disposed on the side of the cover plate close to the flexible display panel, connected between the first shielding portion and the second shielding portion, and at least covering the disconnection portion.

In an exemplary embodiment of the present disclosure, the first shielding portion is an ink layer, the second shielding portion is an ink layer, and the third shielding portion is an ink layer.

In an exemplary embodiment of the present disclosure, a length and a width of a cross section of the display surface of the secondary display panel on a first reference plane are increased as a distance from the main display panel in a second direction increases, wherein the first reference plane is parallel to the display surface of the main display panel, and the second direction is perpendicular to the first reference plane.

In an exemplary embodiment of the present disclosure, the display surface of the secondary display panel is a truncated conical surface or a truncated pyramidal surface.

In an exemplary embodiment of the present disclosure, an orthographic projection of a virtual vertex of the truncated conical surface or the truncated pyramidal surface on the main display panel coincides with a center point of the main display panel.

In an exemplary embodiment of the present disclosure, the main display panel is configured as a rounded rectangle; and the secondary display panel includes:
a first sub-display panel configured in a rectangular shape; and
a second sub-display panel configured in a partially conical ring shape.

In an exemplary embodiment of the present disclosure, four first sub-display panels are provided, four second sub-display panels are provided, and each second sub-display panel is connected between two adjacent first sub-display panels; and two first sub-display panels on two opposite sides of the main display panel have a same angle relative to the first reference plane; extension planes of the two first sub-display panels on the two opposite sides of the main display panel converge to form a virtual straight line; extension planes of the four first sub-display panels converge to form two virtual straight lines, and the two virtual straight lines are perpendicular to each other.

According to another aspect of the present disclosure, a manufacturing method for a display device is provided, including:
providing a flexible display screen and a carrier film, and attaching the flexible display screen to the carrier film;
cutting the flexible display screen and the carrier film to form a patterned display screen and a patterned carrier film, wherein the patterned display screen includes a main display portion and a secondary display portion, and the main display portion and the secondary display portion are each in a flat plate shape; and
profiling the patterned display screen and the patterned carrier film, so that the main display portion is located in a main display area to form a main display panel and the secondary display portion is located in a secondary display area to form a secondary display panel, wherein a display surface of the secondary display panel is formed as an inclined surface, at least part of the secondary display area surrounds a periphery of the main display area, and the main display area is spaced apart from the secondary display area,
wherein an extension plane of the display surface of the secondary display panel converges at a side of the main display panel away from the secondary display panel to form a virtual vertex or a virtual straight line; and a ratio of a distance between the virtual vertex or the virtual straight line and a display surface of the main display panel to a distance between a center point and a boundary line of the main display panel is greater than or equal to 0.2 and less than or equal to 12.

In an exemplary embodiment of the present disclosure, the secondary display portion includes a first portion and a second portion connected to each other; and the patterned display screen further includes:
a connection structure connected between the first portion and the main display portion, wherein a first gap is provided between the second portion and the main display portion, and the connection structure is profiled to form a connection portion.

In an exemplary embodiment of the present disclosure, a width of the first gap in a radial direction increases as a distance from the connection structure increases.

In an exemplary embodiment of the present disclosure, the secondary display portion has a disconnection structure, and the disconnection structure and the connection structure are disposed on two opposite sides of the main display portion.

In an exemplary embodiment of the present disclosure, the patterned display screen further includes:

a first binding structure connected to the main display panel, the first binding structure extending into the disconnection structure, the first binding structure being provided with a plurality of binding pins, and the first binding structure being profiled to form a first binding portion.

In an exemplary embodiment of the present disclosure, the patterned carrier film includes:
a main carrier portion configured to carry the main display portion;
a first carrier portion connected to the main carrier portion and configured to carry the connection structure and the first portion;
two second carrier portions disposed on two opposite sides of the main carrier portion, the second carrier portions being spaced apart from the main carrier portion, and the second carrier portions being configured to carry the second portion; and
a third carrier portion connected to the main carrier portion and configured to carry the first binding structure,
wherein the first carrier portion, the second carrier portion, and the third carrier portion are spaced apart from each other.

In an exemplary embodiment of the present disclosure, the main display portion is configured in a circular shape, and the secondary display portion is configured in a sector ring shape; before cutting the flexible display screen and the carrier film, the manufacturing method further includes:
calculating a parameter of the patterned display screen by using a calculation formula, where the calculation formula includes:

$$\{ \begin{matrix}{L}_{out} = R * ( 360 ° - β ) \\ {L}_{in} = ( R - W ) * ( 360 ° - β )\end{matrix} ;$$

$${L}_{0} = {r}_{0} * θ ;$$

$$D = R - W - {L}_{0} - {r}_{1} ;$$

$${r}_{3} = {r}_{1} + {r}_{0} * Sin θ + {W}_{1} * cos θ ;$$

$$R = {r}_{3} / cos θ ;$$

wherein R is a radius of an edge line of the secondary display portion away from the main display portion in a planar state; β is a central angle corresponding to the disconnection structure in the planar state; D is a distance between a center of the secondary display portion and a center of the main display portion in the planar state; L0 is a width of the connection structure in a radial direction in the planar state; Lout is a length of an edge line of the secondary display panel away from the main display panel; Lin is a length of an edge line of the secondary display panel close to the main display panel; r0 is a radius of curvature of the connection portion in a three-dimensional state; r1 is a radius of the main display panel; W is a width of the secondary display panel in a radial direction; and θ is an angle between the secondary display panel and a first reference plane in the three-dimensional state.

In an exemplary embodiment of the present disclosure, the main display portion is configured as a rounded rectangle; and the secondary display portion includes:
a first sub-display portion configured in a rectangular shape; and
a second sub-display portion configured in a sector ring shape, a central angle corresponding to the second sub-display portion being greater than 0° and less than 90°.

In an exemplary embodiment of the present disclosure, the manufacturing method further includes:
providing a cover plate, and attaching the cover plate to a display surface of the patterned display screen after being profiled.

It should be understood that both the foregoing general description and the following detailed description are exemplary and explanatory only and are not restrictive of the present disclosure.

### BRIEF DESCRIPTION OF THE DRAWINGS

The accompanying drawings, which are incorporated in and constitute a part of this specification, illustrate embodiments consistent with the present disclosure and together with the description, serve to explain the principles of the present disclosure. Apparently, the drawings in the following description are only for illustrating some embodiments of the present disclosure and those skilled in the art can also derive other drawings based on the drawings without paying any creative labor.

FIG. 1 is a perspective schematic view of a display device according to an exemplary embodiment of the present disclosure.

FIG. 2 is a top schematic view of the display device in FIG. 1.

FIG. 3 is a sectional schematic view of the display device in FIG. 1.

FIG. 4 is a structural schematic view of a flexible display panel in FIG. 1.

FIG. 5 is a structural schematic view of an exemplary embodiment of a flexible display panel in a planar state.

FIG. 6 is a structural schematic view of another exemplary embodiment of a flexible display panel in a planar state.

FIG. 7 is a partially enlarged view of a portion indicated by I in FIG. 6.

FIGS. 8-11 are structural schematic views of a connection portion of a flexible display panel.

FIGS. 12-14 are schematic views of a line curvature definition.

FIG. 15 is a perspective schematic view of a display device according to another exemplary embodiment of the present disclosure.

FIG. 16 is a top schematic view of the display device in FIG. 15.

FIG. 17 is a structural schematic view of a flexible display panel in FIG. 15.

FIG. 18 is a schematic view of a layered structure of an exemplary embodiment of a flexible display panel.

FIG. 19 is a schematic view of a layered structure of a display functional layer group in FIG. 18.

FIG. 20 is a schematic view of a layered structure of another exemplary embodiment of a flexible display panel.

FIG. 21 is a sectional schematic view taken along a line A-A in FIG. 16.

FIG. 22 is a sectional schematic view taken along a line B-B in FIG. 16.

FIG. 23 is a flowchart of an exemplary embodiment of a manufacturing method for a display device according to the present disclosure.

FIG. 24 is a structural schematic view showing that a flexible display screen is attached to a carrier film.

FIG. 25 is a structural schematic view after cutting a flexible display screen and a carrier film.

FIG. 26 is a schematic view of a parameter labeling for a sectional schematic view of a display device according to the present disclosure.

FIG. 27 is a schematic view of a parameter labeling for a top schematic view of a flexible display panel of a display device according to the present disclosure.

FIG. 28 is a schematic view of a structure and a parameter labeling of the flexible display panel in FIG. 27 in a planar state.

FIG. 29 is a structural schematic view of an exemplary embodiment of a flexible display panel in FIG. 15 in a planar state.

FIG. 30 is a structural schematic view of another exemplary embodiment of a flexible display panel in FIG. 15 in a planar state.

Reference numerals are listed as follows:
100: flexible display panel; 101: main display panel; 102: secondary display panel; 1021: first display portion; 1022: second display portion; 1023: disconnection portion; 1024: first sub-display panel; 1025: second sub-display panel; 103: connection portion; 1031: via hole; 1032: connection strip; 104: first binding portion; 105: second gap; 106: second binding portion;
1: base layer;
2: display functional layer group; 21: driving backplane; 211: light shielding layer; 212: buffer layer; 2131: channel portion; 2132: source connection portion; 2133: drain connection portion; 214: gate insulating layer; 215: gate; 216: interlayer dielectric layer; 217: first connection conductor layer; 2171: source electrode; 2172: drain electrode; 218: planarization layer;
22: light-emitting substrate; 221: first electrode; 222: pixel define layer; 223: light-emitting layer group; 224: second electrode;
23: encapsulation layer group; 231: first inorganic layer; 232: organic layer; 233: second inorganic layer;
24: touch layer group; 241: first touch layer; 242: touch insulating layer; 243: second touch layer; 244: protective cover layer; 25: polarizer;
3: first bonding layer; 4: protective layer; 5: second bonding layer; 6: touch functional layer;
7: cover plate; 71: main plate; 72: edge plate; 73: connection plate;
81: first shielding portion; 82: second shielding portion; 83: third shielding portion;
9: back functional layer;
200: flexible display screen; 300: patterned display screen; 301: main display portion; 302: secondary display portion; 3021: first portion; 3022: second portion; 3023: disconnection structure; 3023: first sub-display portion; 3024: second sub-display portion; 303: connection structure; 304: first gap; 305: first binding structure;
400: carrier film; 500: patterned carrier film; 501: first carrier portion; 502: second carrier portion; 503: third carrier portion;
ZAA: main display area; FAA: secondary display area;
Y: second direction.

### DETAILED DESCRIPTION

Now, the exemplary embodiments will be described more fully with reference to the accompanying drawings. However, the exemplary embodiments can be embodied in a variety of forms and should not be construed as limiting the embodiments set forth herein. Instead, these embodiments are provided so that the present disclosure will be thorough and complete, and the concepts of the exemplary embodiments will be fully given to those skilled in the art. Same reference numbers denote the same or similar structures in the figures, and thus the detailed description thereof will be omitted. In addition, the drawings are merely schematic illustrations of the present disclosure, and are not necessarily drawn to scale.

Although relative terms such as “above” and “under” are used herein to describe the relationship of one component relative to another component, such terms are used herein only for the sake of convenience, for example, in the direction shown in the figure, it should be understood that if the referenced device is inversed upside down, a component described as “above” will become a component described as “under”. When a structure is described as “above” another structure, it probably means that the structure is integrally formed on another structure, or, the structure is “directly” disposed on another structure, or, the structure is “indirectly” disposed on another structure through a further structure.

Words such as “one,” “an/a” and “said” are used herein to indicate the presence of one or more elements/components/etc. Terms “include” and “have” are used to indicate an inclusive meaning and refer to the possibility of the existence of additional elements/components/etc. in addition to those as listed. Terms “first,” “second” and “third” are used herein only as markers but not limit the number of objects.

In the present disclosure, unless explicitly specified and defined, the term “connect” should be understood in a broad sense, for example, the “connect” may refer to a fixed connection, a detachable connection, or an integral connection; it means to be directly connected or indirectly connected through an intermedia. The term “and/or” is merely a way to describe the relationship between associated objects, indicating the existence of three relationships, for example, A and/or B may represent the existence of A alone, the coexistence of A and B, or the existence of B alone. Additionally, the character “/” herein generally represents that the associated objects before and after it are in an “or” relationship.

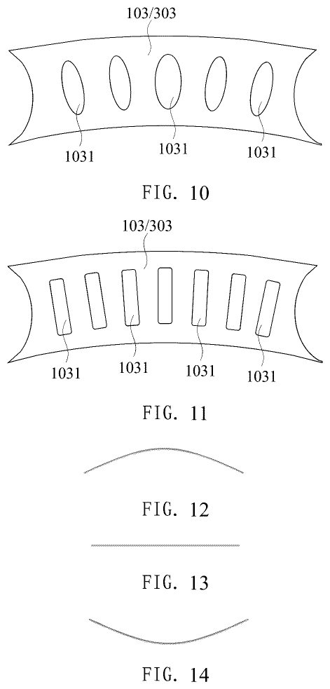

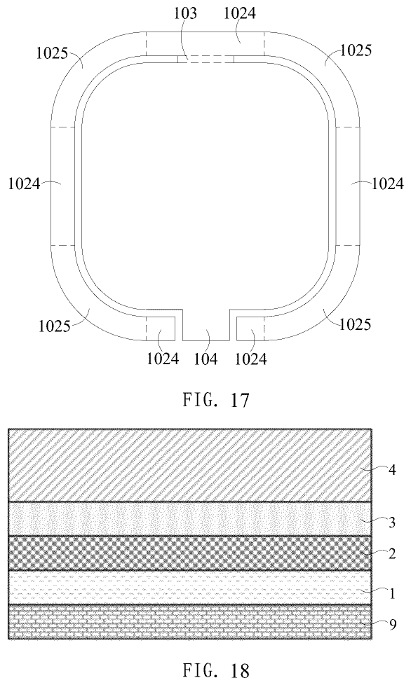

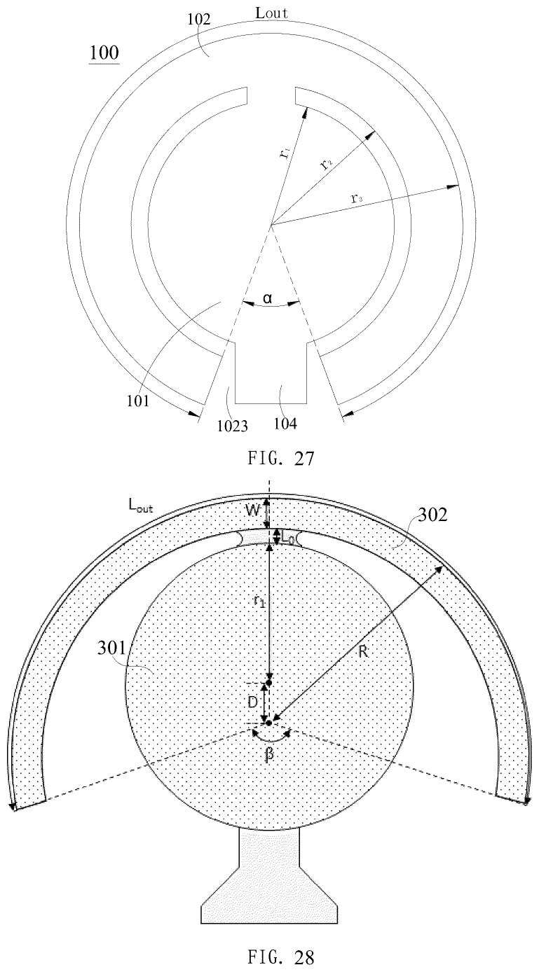

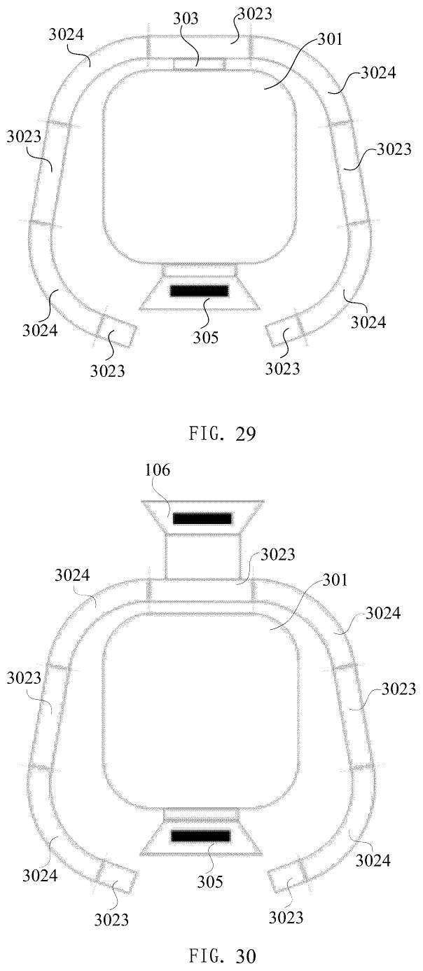

Exemplary embodiments of the present disclosure provide a display device. Referring to FIG. 1 to FIG. 30, the display device has a main display area ZAA and a secondary display area FAA at least partially surrounding a periphery of the main display area ZAA. The main display area ZAA and the secondary display area FAA are spaced apart. The display device may include a flexible display panel 100, and the flexible display panel 100 may include a main display panel 101 and a secondary display panel 102. The main display panel 101 is disposed in the main display area ZAA, and the secondary display panel 102 is disposed in the secondary display area FAA. A display surface of the secondary display panel 102 is configured as an inclined surface; an extension plane of the display surface of the secondary display panel 102 converges at a side of the main display panel 101 away from the secondary display panel 102 to form a virtual vertex or a virtual straight line; and a ratio of a distance between the virtual vertex or the virtual straight line and a display surface of the main display panel 101 to a distance between a center point and a boundary line of the main display panel 101 is greater than or equal to 0.2 and less than or equal to 12.

The display device according to the present disclosure, on one hand, has the main display area ZAA and the secondary display area FAA at least partially surrounding the periphery of the main display area ZAA, so that the display device has an increased display surface and thus improved display and touch efficiency; on the other hand, the main display area ZAA and the secondary display area FAA are spaced apart, so that the main display area ZAA and the secondary display area FAA do not influence with each other, and when a touch operation is performed in the secondary display area FAA, the main display area ZAA will not be shielded, and a display image of the main display area ZAA will not be influenced. Furthermore, since the display surface of the secondary display panel 102 is configured as the inclined surface, even if the secondary display area FAA is increased, a volume of the display device will not be increased too much, which ensures that the display device is wearable and lightweight.

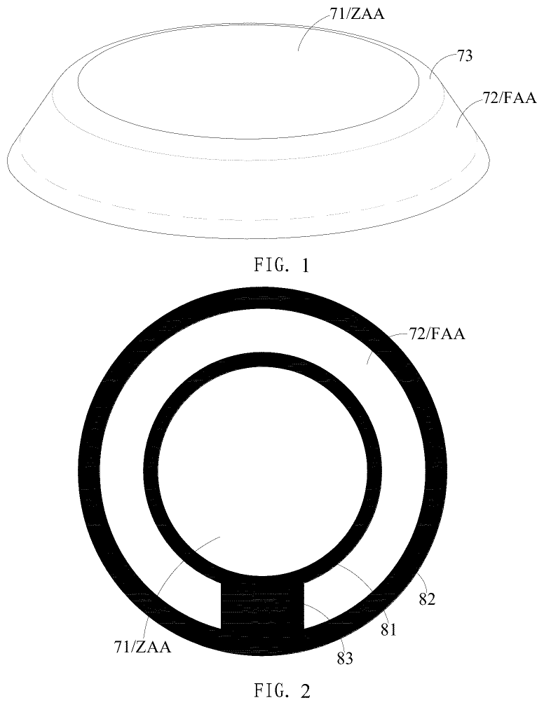

In this exemplary embodiment, referring to FIG. 1 and FIG. 2, the main display area ZAA may be configured in a circular shape, and correspondingly, the secondary display area FAA may be configured in a conical ring shape. Additionally, in some other exemplary embodiments of the present disclosure, the main display area ZAA may be configured in an elliptical shape, and correspondingly, the secondary display area FAA may be configured in an elliptical conical ring shape; the main display area ZAA may be configured in a polygonal shape, and correspondingly, the secondary display area FAA may be configured in a pyramid ring shape. Certainly, the main display area ZAA and the secondary display area FAA may also be configured in other shapes, which will not be elaborated herein. Furthermore, a display surface of the secondary display area FAA is configured as an inclined surface.

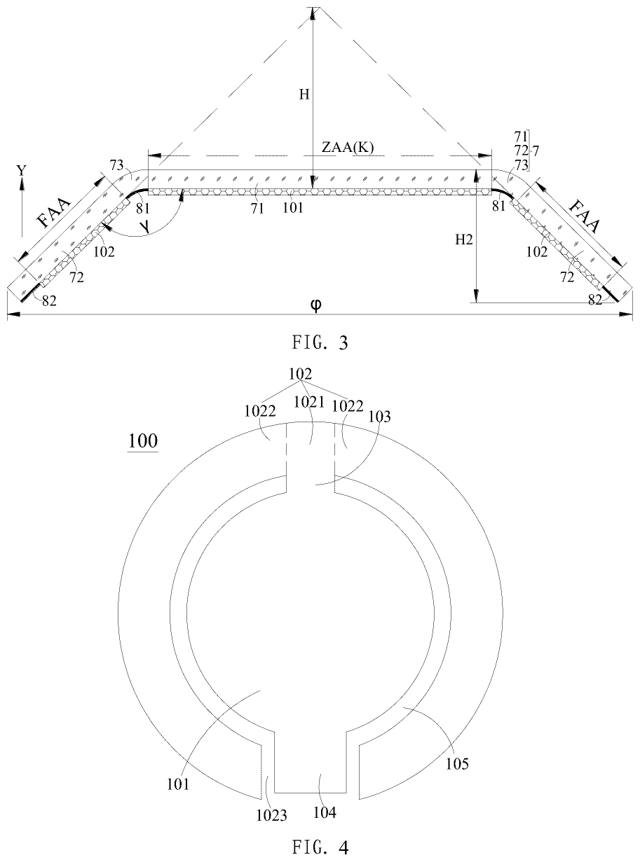

In this exemplary embodiment, the display device may include a flexible display panel 100. Referring to FIG. 3 and FIG. 4, the flexible display panel 100 may include a main display panel 101 and a secondary display panel 102. The main display panel 101 is disposed in the main display area ZAA, the main display panel 101 is configured in a flat plate shape, and a display surface of the main display panel 102 is a flat surface. The main display panel 101 is configured in a shape matching the main display area ZAA. For example, the main display area ZAA may be configured in a circular shape, and correspondingly, the main display panel 101 may be configured in a circular shape; the main display area ZAA may be configured in an elliptical shape, and correspondingly, the main display panel 101 may be configured in an elliptical shape; the main display area ZAA may be configured in a polygonal shape, and correspondingly, the main display panel 101 may be configured in a polygonal shape. Furthermore, a display surface of the main display panel 101 forms the main display area ZAA, that is, an area enclosed by an edge of the display surface of the main display panel 101 is the main display area ZAA.

The secondary display panel 102 is disposed in the secondary display area FAA, and the secondary display panel 102 is configured in a shape matching the secondary display area FAA. For example, the secondary display area FAA may be configured in a conical ring shape, and correspondingly, the secondary display panel 102 may be configured in a conical ring shape; the secondary display area FAA may be configured in an elliptical conical ring shape, and correspondingly, the secondary display panel 102 may be configured in an elliptical conical ring shape; and the secondary display area FAA may be configured in a pyramidal ring shape, and correspondingly, the secondary display panel 102 may be configured in a pyramidal ring shape. Furthermore, a display surface of the secondary display panel 102 forms the secondary display area FAA, that is, an area enclosed by an edge of the display surface of the secondary display panel 102 is the secondary display area FAA.

The secondary display panel 102 has a consistent width throughout.

The display surface of the secondary display panel 102 is configured as an inclined surface. Furthermore, a length and a width of a cross section of the display surface of the secondary display panel 102 on a first reference plane are increased as a distance from the main display panel 101 in a second direction Y increases. That is, the farther away from the main display panel 101 the secondary display panel 102 is, the larger an area of the cross section of the display surface of the secondary display panel 102 is, so that the display surface of the secondary display panel 102 is disposed towards a side of the main display panel 101, which is convenient for a user to use. The first reference plane is parallel to the display surface of the main display panel 102, and the second direction Y is perpendicular to the first reference plane.

Further, the display surface of the secondary display panel 102 is a truncated conical surface or a truncated pyramidal surface. Referring to FIG. 1 to FIG. 3, that is, the display surface of the secondary display panel 102 is a remaining part of a conical surface with a top removed, and the conical surface may be a regular conical surface, that is, an orthographic projection of a vertex of the conical surface on a bottom surface is located at a center of the bottom surface, so that an inclination angle of the secondary display panel 102 at each position is the same, thereby ensuring the display and touch uniformity of the secondary display panel 102. Alternatively, the display surface of the secondary display panel 102 is a remaining part of a pyramidal surface with a top removed, and the pyramidal surface may be a regular pyramidal surface, that is, an orthographic projection of a vertex of the pyramidal surface on a bottom surface is located at a center of the bottom surface, so that an inclination angle of the secondary display panel 102 at each position is the same, thereby ensuring the display and touch uniformity of the secondary display panel 102.

Furthermore, an orthographic projection of a virtual vertex of the truncated conical surface or the truncated pyramidal surface on the main display panel 101 coincides with a center point of the main display panel 101, that is, the center point of the main display panel 101 is collinear with a center of the bottom surface of the truncated conical surface or a center point of the bottom surface of the truncated pyramidal surface, thereby further ensuring the same inclination angle at each position of the secondary display panel 102, and ensuring the display and touch uniformity of the secondary display panel 102.

It should be noted that the virtual vertex of the truncated conical surface or the truncated pyramidal surface is an intersection point formed by extending the truncated conical surface or the truncated pyramidal surface.

A ratio of a distance H between the virtual vertex of the truncated conical surface or the truncated pyramidal surface and the display surface of the main display panel 101 to half of a width K of the main display area ZAA is greater than or equal to 0.2 and less than 12. That is, the ratio of a height H of a triangle formed by the virtual vertex of the truncated conical surface or the truncated pyramidal surface and the display surface of the main display panel 101 to half of a width K of a bottom edge is greater than or equal to 0.2 and less than or equal to 12. In other words, a ratio of the distance H between the virtual vertex and the display surface of the main display panel 101 to a distance K between the center point and the boundary line of the main display panel 101 is greater than or equal to 0.2 and less than or equal to 12. For example, the ratio may be 0.5, 0.8, 1.2, 1.8, 2.3, 2.5, 3.1, 3.7, 4.2, 4.8, 5.3, 5.6, 6.1, 6.7, 7.1, 7.8, 8.2, 8.8, 9.3, 9.6, 10.1, 10.7, 11.1, 11.8, or the like. If the ratio is too large, an inclination angle of a hypotenuse of the triangle is too large, making the inclination angle of the display surface of the secondary display panel 102 too large, and even causing the display surface of the secondary display panel 102 to form a structure perpendicular to the first reference plane, which is not conducive to the user's touch operation and viewing of the secondary display panel 102. If the ratio is too small, the inclination angle of the hypotenuse of the triangle is too small, making the inclination angle of the display surface of the secondary display panel 102 too small, and even causing the display surface of the secondary display panel 102 to form a structure parallel to the first reference plane and causing an overall volume of the display device to increase, which is not conducive to the portability of the wearable display device.

Referring to FIG. 4, the secondary display panel 102 may include a first display portion 1021 and a second display portion 1022 connected to each other. Specifically, two second display portions 1022 may be provided and symmetrically connected to two opposite sides of the first display portion 1021, that is, the second display portion 1022, the first display portion 1021 and the second display portion 1022 are sequentially connected to form the secondary display panel 102. This arrangement can facilitate the design calculation of the secondary display panel 102; and since the secondary display panel 102 needs to be formed by bending, this arrangement can reduce bending stress, avoid warping of the secondary display panel 102 and ensure a display effect. In this case, the second display portion 1022 is configured to be smaller than a semi-annular sector ring structure, that is, a central angle corresponding to an inner edge or an outer edge of the second display portion 1022 is less than 90°. Certainly, in some other exemplary embodiments of the present disclosure, one second display portion 1022 is provided, and the second display portion 1022 is connected to one side of the first display portion 1021. In this case, the second display portion 1022 is configured to be larger than a semi-annular sector ring structure, that is, a central angle corresponding to the inner edge or the outer edge of the second display portion 1022 is greater than 90°.

The secondary display panel 102 is connected to the main display panel 101 as a whole. Specifically, the flexible display panel 100 may further include a connection portion 103, the connection portion 103 is connected between the first display portion 1021 and the main display panel 101, and the second display portion 1022 is spaced apart from the main display panel 101, so that a second gap 105 is provided between the second display portion 1022 and the main display panel 101, and the second gap 105 is also configured as a structure smaller than a semi-annular shape.

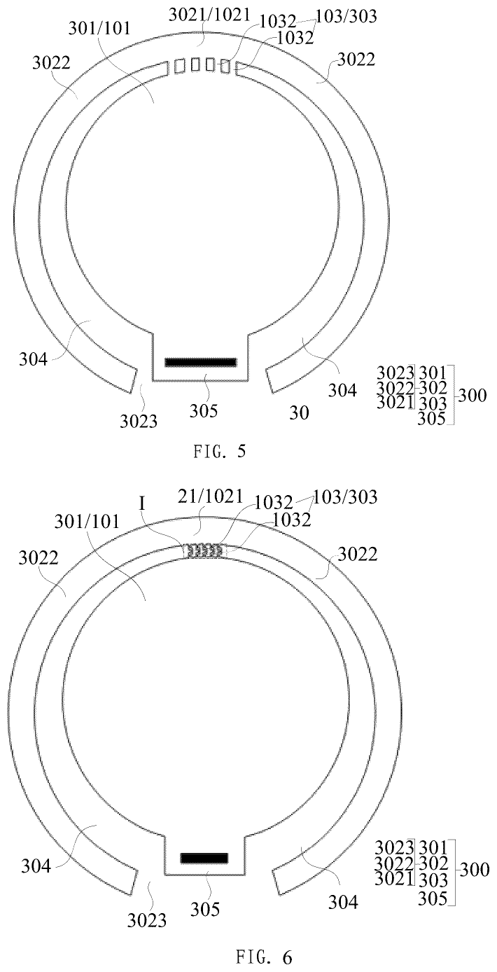

Referring to FIG. 5 and FIG. 6, in order to clearly show a specific structure of the connection portion 103, a three-dimensional flexible display panel 100 is unfolded into a planar patterned display screen 300. In the figures, a planar connection structure 303 may be profiled to form the three-dimensional connection portion 103.

Referring to FIG. 5 and FIG. 6, the connection portion 103 may include at least two connection strips 1032, one end of each connection strip 1032 is connected to the main display panel 101, and the opposite other end of each connection strip 1032 is connected to the first display portion 1021. The number of the connection strips 1032 may be set as needed. Referring to FIG. 5, the connection strips 1032 may be arranged in the shape of linear strips. The connection portion 103 arranged in this way has certain stretchability, which can better fit with a connection plate 73 of a cover plate 7.

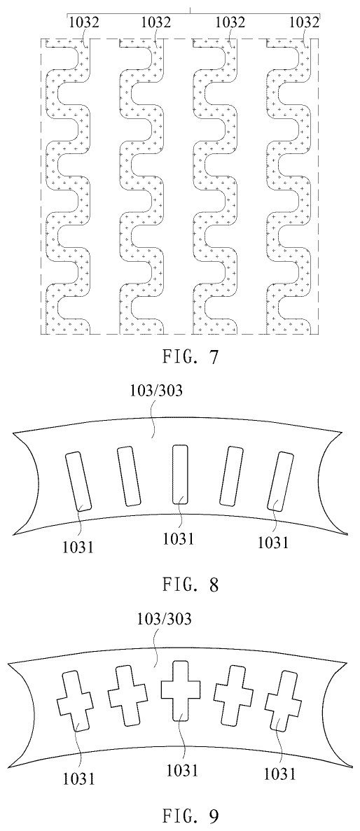

Referring to FIG. 6 and FIG. 7, each connection strip 1032 is configured in a curved shape; specifically, the connection strip 1032 may be configured in a rectangular curved shape, i.e., a plurality of rectangular notch portions are provided at intervals on two opposite sides of the straight strip. Each connection strip 1032 may be configured in an arc curved shape, i.e., the connection strips 1032 may include one, two or more arc-shaped strips, and two adjacent arc-shaped strips are smoothly connected. The curved connection strip 1032 may also be of a structure in which a rectangular curved strip is connected to an arc curved strip. The curved connection strip 1032 may also have other shapes, which will not be elaborated herein. Likewise, the connection portion 103 arranged in this way has certain stretchability, which can better fit with the connection plate 73 of the cover plate 7.

Referring to FIGS. 8-11, the connection portion 103 is provided with a plurality of via holes 1031, and each via hole 1031 may be shaped in a rectangle, an ellipse, a waist circle, a cross or the like. The connection portion 103 provided with the plurality of via holes 1031 has certain stretchability, and likewise can better fit with the connection plate 73 of the cover plate 7. The number of the via holes 1031 may be set as needed. A maximum dimension (including length, width, diameter) of each via hole 1031 is greater than or equal to 0.005 mm and less than or equal to 1 mm.

In addition, when the main display panel 101 is configured in a circular shape, the plurality of via holes 1031 are arranged along a circular arc at equal rotation angles, and the circular arc may be concentric with a center of the main display panel 101 or concentric with a center of the secondary display panel 102. Central lines of the plurality of via holes 1031 pass through a center of the circular arc, and an angle between central lines of two adjacent via holes 1031 is the same, so that the plurality of via holes 1031 are arranged along the circular arc at equal rotation angles, thereby ensuring the uniformity of stretching performance throughout the connection portion 103.

In a case where the main display panel 101 is configured in a rectangular shape, the plurality of via holes 1031 are arranged along a straight line at equal intervals, or the via holes 1031 may not be provided.

In this exemplary embodiment, still referring to FIG. 4, the secondary display panel 102 has a disconnection portion 1023; specifically, the disconnection portion 1023 is disposed between the two second display portions 1022, that is, the secondary display panel 102 is broken by the disconnection portion 1023 to form the two second display portions 1022. The disconnection portion 1023 and the connection portion 103 are disposed on two opposite sides of the main display panel 101, to further ensure that the two second display portions 1022 are symmetrically disposed, thereby ensuring stress balance of the secondary display panel 102, and ensuring a display and touch effect.

Referring to FIG. 4, the flexible display panel 100 may further include a first binding portion 104, the first binding portion 104 is connected to the main display panel 101, and the first binding portion 104 and the connection portion 103 are disposed on two opposite sides of the main display panel 101. That is, the first binding portion 104 is connected to a side of the main display panel 101 away from the connection portion 103, and the first binding portion 104 extends to the disconnection portion 1023, i.e., an orthographic projection of the first binding portion 104 on the first reference plane overlaps with an orthographic projection of the disconnection portion 1023 on the first reference plane. For example, the orthographic projection of the first binding portion 104 on the first reference plane is located within the orthographic projection of the disconnection portion 1023 on the first reference plane, or a part of the orthographic projection of the first binding portion 104 on the first reference plane is located within the orthographic projection of the disconnection portion 1023 on the first reference plane, so that the part of the first binding portion 104 extends into the disconnection portion 1023. The first binding portion 104 is provided with a plurality of binding pins, the plurality of binding pins may be bound to a display driving chip, and the display driving chip may control the display and touch of the main display panel 101 and the secondary display panel 102.

Referring to FIGS. 1-3, the display device may further include a cover plate 7 on the display surface of the flexible display panel 100, and the cover plate 7 may protect the display panel.

Specifically, the cover plate 7 may include a main plate 71 and an edge plate 72, and the edge plate 72 is connected to a periphery of the main plate 71. The main plate 71 is disposed in the main display area ZAA; the main plate 71 is disposed on a side of the display surface of the main display panel 101; and the main plate 71 is configured in a flat plate shape. The main plate 71 is configured in a shape matching the main display area ZAA. For example, the main display area ZAA may be configured in a circular shape, and correspondingly, the main plate 71 may be configured in a circular shape; the main display area ZAA may be configured in an elliptical shape, and correspondingly, the main plate 71 may be configured in an elliptical shape; the main display area ZAA may be configured in a polygonal shape, and correspondingly, the main plate 71 may be configured in a polygonal shape. A specific size of the main plate 71 may be set as required.

An orthographic projection of the main plate 71 on the first reference plane is located within an orthographic projection of the main display panel 101 on the first reference plane. For example, the orthographic projection of the main plate 71 on the first reference plane may overlap with the orthographic projection of the main display panel 101 on the first reference plane, or an edge line of the orthographic projection of the main plate 71 on the first reference plane may be located inside an edge line of the orthographic projection of the main display panel 101 on the first reference plane. In this case, an edge line of an orthographic projection of a display area of the main display panel 101 on the first reference plane may overlap with the orthographic projection of the main plate 71 on the first reference plane, but an edge area of the main display panel 101 may be provided with dummy pixels (virtual pixels), orthographic projections of the dummy pixels on the first reference plane are located outside the edge line of the orthographic projection of the main plate 71 on the first reference plane. This arrangement allows the display surface of the main display panel 101 to be completely located in the main display area ZAA.

The edge plate 72 is disposed in the secondary display area FAA, and a surface of the edge plate 72 close to the flexible display panel 100 is configured as an inclined surface, i.e., the surface of the edge plate 72 close to the flexible display panel 100 is attached to the display surface of the secondary display panel 102. Since the display surface of the secondary display panel 102 needs to be attached to the surface of the edge plate 72 close to the flexible display panel 100, the surface of the edge plate 72 close to the flexible display panel 100 has a same structure as the display surface of the secondary display panel 102, which will not be elaborated herein.

In a case where a thickness throughout the edge plate 72 is the same, the edge plate 72 may be configured in a truncated conical cylinder shape. The edge plate 72 is configured in a shape matching the secondary display area FAA. For example, the secondary display area FAA may be configured in a conical ring shape, and correspondingly, the edge plate 72 may be configured as a truncated conical cylinder shape; the secondary display area FAA may be configured in an elliptical conical ring shape, and correspondingly, the edge plate 72 may be configured as a truncated elliptical conical cylinder shape; the secondary display area FAA may be configured in a pyramidal ring shape, and correspondingly, the edge plate 72 may be configured as a truncated pyramidal cylinder shape. A width throughout the edge plate 72 remains consistent.

An angle γ between a surface of the edge plate 72 close to the flexible display panel 100 and a surface of the main plate 71 close to the flexible display panel 100 is greater than 900 and less than or equal to 179°. For example, the angle γ between the edge plate 72 and the main plate 71 may be 95°, 104°, 108°, 112°, 117°, 120°, 122.5°, 128°, 133°, 137°, 142°, 148°, 150°, 152.5°, 157°, 161°, 165°, 168°, 166°, 176°, and the like.

On the first reference plane, a distance between an end of the edge plate 72 close to the main plate 71 and the main plate 71 is greater than or equal to 0.017 mm, to ensure that a gap between the edge plate 72 and the main plate 71 is small, to avoid affecting the display effect, and enabling the cover plate 7 to form a certain bending angle.

A distance H2 between another end of the edge plate 72 away from the main plate 71 and the main plate 71 is greater than or equal to 1 mm and less than or equal to 12 mm. For example, the distance H2 between the end of the edge plate 72 away from the main plate 71 and the main plate 71 may be 1.3 mm, 1.7 mm, 2.1 mm, 2.6 mm, 3 mm, 3.5 mm, 4.1 mm, 4.7 mm, 5.3 mm, 5.7 mm, 6.1 mm, 6.6 mm, 7 mm, 7.5 mm, 8.3 mm, 8.8 mm, 9.1 mm, 9.6 mm, 10 mm, 11.5 mm, 11.8 mm, etc.

In a case where the display device is configured in a circular shape, a diameter Y of the cover plate 7 is greater than or equal to 10 mm and less than or equal to 90 mm. For example, the diameter φ of the cover plate 7 may be 13 mm, 17 mm, 21 mm, 25 mm, 26 mm, 30 mm, 35 mm, 41 mm, 47 mm, 50 mm, 53 mm, 57 mm, 61 mm, 66 mm, 70 mm, 75 mm, 83 mm, 88 mm, etc.

In a case where the display device is configured in a square shape, a length and a width of the cover plate 7 are greater than or equal to 10 mm and less than or equal to 90 mm. For example, the length and the width of the cover plate 7 may be 13 mm, 17 mm, 21 mm, 25 mm, 26 mm, 30 mm, 35 mm, 41 mm, 47 mm, 50 mm, 53 mm, 57 mm, 61 mm, 66 mm, 70 mm, 75 mm, 83 mm, 88 mm, etc.

It should be noted that limitations on the cover plate 7 are on a surface of the cover plate 7 close to the flexible display panel 100, while there is no limitation on a surface of the cover plate 7 away from the flexible display panel 100, and the surface of the cover plate 7 away from the flexible display panel 100 may be set as required.

Still referring to FIG. 3, in this exemplary embodiment, the cover plate 7 may further include a connection plate 73, the connection plate 73 is connected between the main plate 71 and the edge plate 72, and the connection plate 73 has a positive Gaussian curvature.

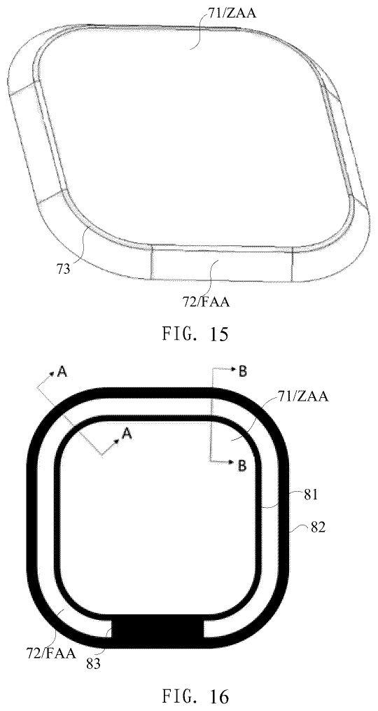

An infinite number of lines may be made through a point on a curved surface, and it is assumed that a curvature of these lines is positive for convexity (the more convex the line is, the greater curvature is), as shown in FIG. 12; zero for flatness, as shown in FIG. 13; negative for concavity (the smaller the concave curvature is), as shown in FIG. 14. The Gaussian curvature of a point on the curved surface=max {curvatures of all lines passing through the point}×min {curvatures of all lines passing through the point}, and the lines corresponding to the maximum curvature and the minimum curvature (also referred to as principal curvatures) are orthogonal.

For a planarly fabricated flexible display panel 100, a line passing through any point on the flexible display panel 100 is a straight line, so the Gaussian curvature of all points of the flexible display panel 100=0×0.

When the flexible display panel 100 is bent into a cylindrical surface or a conical surface, although the form changes from a plane to a curved surface, there is always a straight line passing through each point on the flexible display panel 100, so the Gaussian curvature of any point on the cylindrical surface or the conical surface=positive×0, which is still 0.

Therefore, it may be concluded that: if a curved surface is formed by arbitrary bending, the Gaussian curvature of the curved surface must remain unchanged, as long as the curved surface is not stretched, compressed or torn, determining whether a curved surface is an expandable curved surface is to determine whether the Gaussian curvature of the curved surface is 0. For a three-dimensional curved display with a non-zero Gaussian curvature, stretchable/compressible technology must be applied for the sake of feasibility, that is, if a three-dimensional curved display with a non-zero Gaussian curvature is to be formed, the flexible display panel 100 must be stretched or compressed.

Since the connection plate 73 is not only bent along a circumferential direction of the main display panel 101 but also bent and connected to the secondary display panel 102 from the main display panel 101, the Gaussian curvature of the connection plate 73 is positive. Since the connection portion 103 is attached to the connection plate 73, and specifically, the connection portion 103 is bonded to the connection plate 73, so that a Gaussian curvature of the connection portion 103 is also positive, and thus the connection structure 303 of the planar patterned display screen 300 needs to be stretched or compressed to be attached to the connection plate 73. The connection portion 103 is configured in a structure with stretching properties describe above, which enables the connection portion 103 to fit well with the connection plate 73 and ensures the display effect of the display device.

Referring to FIG. 2 and FIG. 3, the display device may further include a first shielding portion 81 disposed on a side of the cover plate 7 close to the flexible display panel 100, the first shielding portion 81 is an ink layer coated on the side of the cover plate 7 close to the flexible display panel 100, and the first shielding portion 81 is located between the main display area ZAA and the secondary display area FAA. Since the connection plate 73 is also located between the main display area ZAA and the secondary display area FAA, the first shielding portion 81 coated on a side of the connection plate 73 close to the flexible display panel 100 may shield a gap between the connection portion 103 and the main display area ZAA and a gap between the connection portion 103 and the secondary display area FAA, so as to prevent other devices or circuits disposed on a side of the flexible display panel 100 away from the cover plate 7 from being viewed by the user and from affecting an overall display effect of the display device. Furthermore, some dummy pixels may be provided in an edge area of the main display panel 101, and these dummy pixels may be shielded by the first shielding portion 81, so as to avoid being viewed by the user and affecting the overall display effect of the display device.

The first shielding portion 81 is configured in a shape matching the main display area ZAA. For example, the main display area ZAA may be configured in a circular shape, and correspondingly, the first shielding portion 81 may be configured in a circular ring shape. In addition, in some other exemplary embodiments of the present disclosure, the main display area ZAA may be configured in an elliptical shape, and correspondingly, the first shielding portion 81 may be configured in an elliptical ring shape; the main display area ZAA may be configured in a polygonal shape, and correspondingly, the first shielding portion 81 may be configured in a polygonal ring shape. Certainly, the main display area ZAA and the first shielding portion 81 may also have other shapes, which will not be elaborated herein.

Still referring to FIG. 2 and FIG. 3, the display device may further include a second shielding portion 82 disposed on the side of the cover plate 7 close to the flexible display panel 100, the second shielding portion 82 is an ink layer coated on the side of the cover plate 7 close to the flexible display panel 100, and the second shielding portion 82 is located on a side of the secondary display area FAA away from the main display area ZAA. Some dummy pixels may be provided in an edge area of the secondary display panel 102, and these dummy pixels may be shielded by the first shielding portion 81, so as to avoid being viewed by the user and affecting the overall display effect of the display device.

The second shielding portion 82 is configured in a shape matching the secondary display area FAA. For example, the secondary display area FAA may be configured in a conical ring shape, and correspondingly, the second shielding portion 82 may be configured in a conical ring shape; the secondary display area FAA may be configured in an elliptical conical ring shape, and correspondingly, the second shielding portion 82 may be configured in an elliptical conical ring shape; the secondary display area FAA may be configured in a pyramidal ring shape, and correspondingly, the second shielding portion 82 may be configured in a pyramidal ring shape.

Still referring to FIG. 2 and FIG. 3, the display device may further include a third shielding portion 83 disposed on the side of the cover plate 7 close to the flexible display panel 100, the third shielding portion 83 is an ink layer coated on the side of the cover plate 7 close to the flexible display panel 100, and the third shielding portion 83 is connected between the first shielding portion 81 and the second shielding portion 82. The third shielding portion 83 at least covers the disconnection portion 1023, and an orthographic projection of the disconnection portion 1023 on the first reference plane is located within an orthographic projection of the third shielding portion 83 on the first reference plane; for example, the orthographic projection of the disconnection portion 1023 on the first reference plane overlaps with the orthographic projection of the third shielding portion 83 on the first reference plane, or the orthographic projection of the third shielding portion 83 on the first reference plane covers and is greater than the orthographic projection of the disconnection portion 1023 on the first reference plane. The disconnection portion 1023 may be shielded by the third shielding portion 83, to prevent the first binding portion 104 and other devices or circuits disposed on the side of the flexible display panel 100 away from the cover plate 7 from being viewed by the user and from affecting the overall display effect of the display device.

Certainly, the first shielding portion 81, the second shielding portion, and the third shielding portion 83 may also be made of other light shielding materials, and may be formed on the side of the cover plate 7 close to the flexible display panel 100 by a process such as sputtering and deposition.

Referring to FIGS. 15-17, the main display panel 101 is configured as a rounded rectangle. That is, the main display panel 101 includes four straight edges and four rounded edges; the four straight edges and the four rounded edges are alternately arranged and connected from head to tail into a loop. The secondary display panel 102 may include a first sub-display panel 1024 and a second sub-display panel 1025; the first sub-display panel 1024 is configured in a rectangular shape and disposed on a side of the straight edge; and the second sub-display panel 1025 is configured in a partially conical ring shape and disposed on a side of the rounded edge.

Specifically, there may be four first sub-display panels 1024, and since one of the first sub-display panels 1024 is provided with the disconnected portion 1023, this first sub-display panel 1024 is divided into two parts by the disconnected portion, or a length of this first sub-display panel 1024 is shorter than lengths of other first sub-display panels 1024. There may be four second sub-display panels 1025, each second sub-display panel 1025 is connected between two adjacent first sub-display panels 1024, and the four first sub-display panels 1024 and the four second sub-display panels 1025 are alternately arranged. Two first sub-display panels 1024 located on two opposite sides of the main display panel 101 have a same angle relative to the first reference plane, and extension planes of the two first sub-display panels 1024 located on two opposite sides of the main display panel 101 converge to form a virtual straight line. Extension planes of the four first sub-display panels 1024 converge to form two virtual straight lines, the two virtual straight lines are perpendicularly arranged, and the two virtual straight lines may converge in a common plane, so that the four first sub-display panels 1024 have the same angle relative to the first reference plane. The two virtual straight lines may not be located in the same plane, i.e., the two virtual straight lines have different distances relative to the display surface of the display panel.

In addition, referring to FIG. 30 that is a structural schematic view of the flexible display panel in a planar state, a main display portion 301 forms the main display panel 101, and a secondary display portion 302 forms the secondary display panel 102. The connection portion 103 may not be provided between the main display panel 101 and the secondary display panel 102, i.e., the main display panel 101 is spaced apart from the secondary display panel 102 are spaced apart. In this case, the flexible display panel may further include a second binding portion 106, the second binding portion 106 is connected to the secondary display panel 102 and located on a side of the secondary display panel 102 away from the main display panel 101, and the second binding portion 106 is also provided with a plurality of binding pins, which may be bound to the display driving chip, and the display driving chip may control the display and touch of the secondary display panel 102.

It should be noted that FIG. 30 merely shows a structure in which the connection portion 103 may not be provided between the main display panel 101 and the secondary display panel 102 and the second binding portion 106 is provided, and does not limit that this structure may only be used for a rounded rectangular display device, but rather this structure may also be used for a circular display device shown in FIG. 1, and may also be used for other elliptical or various polygonal display devices.

The flexible display panel 100 may be an OLED (Organic Electroluminescence Display) flexible display panel 100, a QLED (Quantum Dot Light Emitting Diodes) flexible display panel 100, or the like. The flexible display panel 100 has a light-exiting side and a nonluminous side arranged opposite to each other; an image may be displayed on the light-exiting side, and a surface displaying the image is the display surface.

The OLED flexible display panel 100 will be described as an example below.

Referring to FIG. 18, the flexible display panel 100 may include a base layer 1, a display functional layer group 2, a first bonding layer 3, and a protective layer 4. The display functional layer group 2 is disposed on a side of the base layer 1. The first bonding layer 3 is disposed on a side of the display functional layer group 2 away from the base layer 1. The protective layer 4 is disposed on a side of the first bonding layer 3 away from the base layer 1, and the protective layer 4 and the display functional layer group 2 are bonded together through the first bonding layer 3.

The base layer 1 is a flexible substrate layer, and may provide support for each functional layer. The material of the base layer 1 may include an inorganic material; for example, the inorganic material may be glass, quartz or metal. The material of the base layer 1 may further include an organic material; for example, the organic material may be a resin material such as polyimide, polycarbonate, polyacrylate, polyetherimide, polyethersulfone, polyethylene terephthalate, and polyethylene naphthalate. The base layer 1 may be formed from a plurality of material layers; for example, the base layer 1 may include a plurality of substrate layers, and the material of the substrate layers may be any one of the above materials. Certainly, the base layer 1 may also be provided as a single layer, which may be any of the above materials.

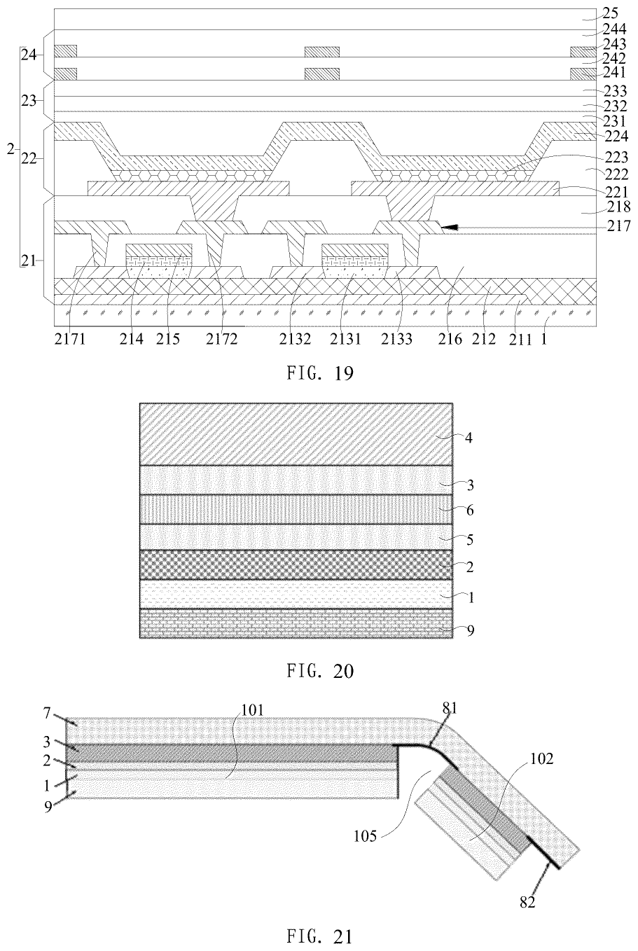

Referring to FIG. 19, the display functional layer group 2 may include a driving backplane 21, a light-emitting substrate 22, and an encapsulation layer group 23. The driving backplane 21 is disposed on a side of the base layer 1. The light-emitting substrate 22 is disposed on a side of the driving backplane 21 away from the base layer 1. The encapsulation layer group 23 is disposed on a side of the light-emitting substrate 22 away from the base layer 1.

Referring to FIG. 19, the driving backplane 21 may include a plurality of drive circuits arranged in an array; the light-emitting substrate 22 may include a plurality of light-emitting devices arranged in an array; and the drive circuits may drive the light-emitting devices to emit light. The light-emitting substrate 22 is electrically connected to the driving backplane 21, and the driving backplane 21 is configured to drive the light-emitting substrate 22 to emit light.

Referring to FIG. 19, a light shielding layer 211 may be further provided on one side of the base layer 1, and light incident into an active layer from the base layer 1 may generate photo-generated carriers in the active layer, which in turn will have a great effect on characteristics of a thin film transistor and finally affect the display image quality of the display device. The light shielding layer 211 may shield light rays from the base layer 1, to avoid affecting the characteristics of the thin film transistor and affecting the display image quality of the display device. Depending on the type of the thin film transistor, the light shielding layer 211 may be omitted.

A buffer layer 212 may also be formed on a side of the light shielding layer 211 away from the base layer 1. The buffer layer 212 functions to block water vapor and impurity ions in the base layer 1 (especially organic materials), and functions to add hydrogen ions to the subsequently formed active layer. The buffer layer 212 is made of an insulating material that may insulate the light shielding layer 211 from the active layer. The buffer layer 212 may include silicon nitride, silicon oxide, or silicon oxynitride. Depending on the type or process conditions of the base layer 1, the buffer layer 212 may be omitted.

The active layer is disposed on a side of the buffer layer 212 away from the base layer 1. The active layer may include a channel portion 2131 and conductor portions disposed at two ends of the channel portion 2131, and one of the two conductor portions is a source connection portion 2132, while the other thereof is a drain connection portion 2133. A gate insulating layer 214 is disposed on a side of the active layer away from the base layer 1; a gate 215 is disposed on a side of the gate insulating layer 214; an interlayer dielectric layer 216 is disposed on a side of the gate 215 away from the base layer 1; the interlayer dielectric layer 216 is provided with a through hole, and the through hole is in communication with the conductor portion. A first connection conductor layer 217 is disposed on a side of the interlayer dielectric layer 216 away from the base layer 1; the first connection conductor layer 217 may include a source electrode 2171 and a drain electrode 2172; the source electrode 2171 is connected to the source connection portion 2132 through a via hole in the interlayer dielectric layer 216; and the drain electrode 2172 is connected to the drain connection portion 2133 through a via hole in the interlayer dielectric layer 216. A planarization layer 218 is disposed on a side of the first connection conductor layer 217 away from the base layer 1; the planarization layer 218 is provided with a through hole, and the through hole is connected to the drain electrode 2172. The channel portion 2131, the gate 215, the source electrode 2171, and the drain electrode 2172 form the thin film transistor.

In some other exemplary embodiments of the present disclosure, a passivation layer is disposed on the side of the first connection conductor layer 217 away from the base layer 1, and the passivation layer is also provided with a via hole. A second connection conductor layer is disposed on a side of the passivation layer away from the base layer 1; the second connection conductor layer may include a second source connection line and/or a second drain connection line; and the second source connection line and the second drain connection line are correspondingly connected to the source electrode 2171 and the drain electrode 2172 through via holes in the passivation layer. Certainly, a third connection conductor layer, a fourth connection conductor layer and the like may also be provided as required.

It should be noted that the thin film transistor described in this specification is a top gate type thin film transistor, and in other exemplary embodiments of the present disclosure, the thin film transistor may also be a bottom gate type or a double gate type, and the specific structure thereof will not be elaborated herein. Furthermore, functions of the “source electrode 2171” and the “drain electrode 2172” are sometimes exchanged with each other when thin film transistors with opposite polarities are used or when a current direction changes in circuit operation. Thus, in this specification, the “source electrode 2171” and the “drain electrode 2172” may be interchanged.

Referring to FIG. 19, the light-emitting substrate 22 is disposed on a side of the planarization layer 218 away from the base layer 1, and the light-emitting substrate 22 may include a first electrode 221, a pixel define layer 222, a light-emitting layer group 223, and a second electrode 224.

Specifically, the first electrode 221 is disposed on the side of the planarization layer 218 away from the base layer 1, the first electrode 221 is connected to the drain electrode 2172 of the driving backplane 21 through a through hole, and the first electrode 221 may be an anode (a pixel electrode).

The pixel define layer 222 is disposed on a side of the first electrode 221 away from the base layer 1, the pixel define layer 222 is provided with an opening portion, and the opening portion is in communication with the first electrode 221, so that at least part of the first electrode 221 is not covered by the pixel define layer 222.

The light-emitting layer group 223 is disposed on a side of the pixel define layer 222 away from the base layer 1, and at least part of the light-emitting layer group 223 is located in the opening portion. The second electrode 224 is disposed on a side of the light-emitting layer group 223 away from the base layer 1, and the second electrode 224 may be a cathode (a common electrode). The light-emitting layer group 223 in one opening portion emits light to form one sub-pixel, so that an orthographic projection of the sub-pixel on the base layer 1 is an orthographic projection of the light-emitting layer group 223 in the opening portion on the base layer 1, and the flexible display panel 100 may include a plurality of sub-pixels.

The light-emitting layer group 223 may include a hole injection layer, a hole transport layer, an organic light-emitting layer, an electron transport layer, and an electron injection layer that are sequentially laminated; the hole injection layer is in contact with the first electrode 221, and the electron injection layer is in contact with the second electrode 224. Certainly, in other exemplary embodiments of the present disclosure, the light-emitting layer group 223 may only include a hole transport layer, a light-emitting layer and an electron transport layer, and the light-emitting layer group 223 may also be of other structures, and the specific structures thereof may be set as required.

Holes are injected into the organic light-emitting layer from the side of the first electrode 221, electrons are injected into the organic light-emitting layer from the side of the second electrode 224, and finally the holes and the electrons are compounded in the organic light-emitting layer to generate excitons. When the generated excitons are relaxed from an excited state to a ground state, the OLED emits visible light.

The encapsulation layer group 23 is disposed on a side of the second electrode 224 away from the base layer 1. Referring to FIG. 19, the encapsulation layer group 23 may be configured in multiple layers, and the encapsulation layer group 23 may include an organic layer 232 and an inorganic layer. Specifically, the encapsulation layer group 23 may include a first inorganic layer 231, an organic layer 232 disposed on a side of the first inorganic layer 231 away from the base layer 1, and a second inorganic layer 233 disposed on a side of the organic layer 232 away from the base layer 1. Materials of the first inorganic layer 231, the organic layer 232, and the second inorganic layer 233 are not elaborated herein. Certainly, the encapsulation layer group 23 may also include more layers or fewer layers.

Referring to FIG. 19, the display functional layer group 2 may further include a touch layer group 24 and a polarizer 25.

In this exemplary embodiment, referring to FIG. 19, the touch layer group 24 is disposed on a side of the encapsulation layer group 23 away from the base layer 1. The touch layer group 24 may include a first touch layer 241, a touch insulating layer 242, a second touch layer 243, and a protective cover layer 244. The first touch layer 241 is disposed on the side of the encapsulation layer group 23 away from the base layer 1, and the first touch layer 241 may have a Ti/Al/Ti three-layer structure, an ITO/Ag/ITO three-layer structure, or the like. The touch insulating layer 242 is disposed on a side of the first touch layer 241 away from the base layer 1, and a material of the touch insulating layer 242 may be SiNx material. The second touch layer 243 is disposed on a side of the touch insulating layer 242 away from the base layer 1, and the second touch layer 243 may have a Ti/Al/Ti three-layer structure, an ITO/Ag/ITO three-layer structure, or the like. The protective cover layer 244 is disposed on a side of the second touch layer 243 away from the base layer 1, and a material of the protective cover layer 244 is PI (polyimide). The first touch layer 241 and the second touch layer 243 may be connected to the driving backplane 21 through the encapsulation layer group 23 and a via hole on a barrier layer, and then connected to the first binding portion 104 through the driving backplane 21. Certainly, the materials and structures of the above film layers are merely examples, and may also be selected as needed.

The polarizer 25 may be disposed on a side of the touch layer group 24 away from the base layer 1; the first bonding layer 3 may be disposed on a side of the polarizer 25 away from the base layer 1; the protective layer 4 may be bonded on the side of the first bonding layer 3 away from the base layer 1; and the cover plate 7 may be bonded on a side of the protective layer 4 away from the base layer 1. The protective layer 4 may protect the display functional layer group 2, to prevent friction between a display surface of the display functional layer group 2 and the cover plate 7, which may otherwise affect display of the display functional layer group 2.

In some other exemplary embodiments of the present disclosure, the display functional layer group 2 may not include the touch layer group 24 and the polarizer 25. Referring to FIG. 20, a second bonding layer 5 is provided on the side of the display functional layer group 2 away from the base layer 1, and a touch functional layer 6 is bonded to a side of the second bonding layer 5 away from the base layer 1, and a specific structure of the touch functional layer 6 may be the same as a specific structure of the touch layer group 24 and thus will not be elaborated herein. The touch functional layer 6 needs to extend to the first binding portion 104 to be bound; i.e., the touch functional layer 6 is an external structure. The polarizer 25 may also be bonded to a side of the touch functional layer 6 away from the base layer 1, the first bonding layer 3 is disposed on the side of the polarizer 25 away from the base layer 1, the protective layer 4 may be bonded to the side of the first bonding layer 3 away from the base layer 1, and the cover plate 7 may be bonded to the side of the protective layer 4 away from the base layer 1.

Referring to FIG. 18 and FIG. 20, a back functional layer 9 may be provided on a side of the base layer 1 away from the display functional layer group 2. The back functional layer 9 may include a buffer material layer, a heat dissipation layer, or the like.

Referring to FIG. 21, no film layer of the flexible display panel is provided in the second gap 105 between the main display panel 101 and the secondary display panel 102.

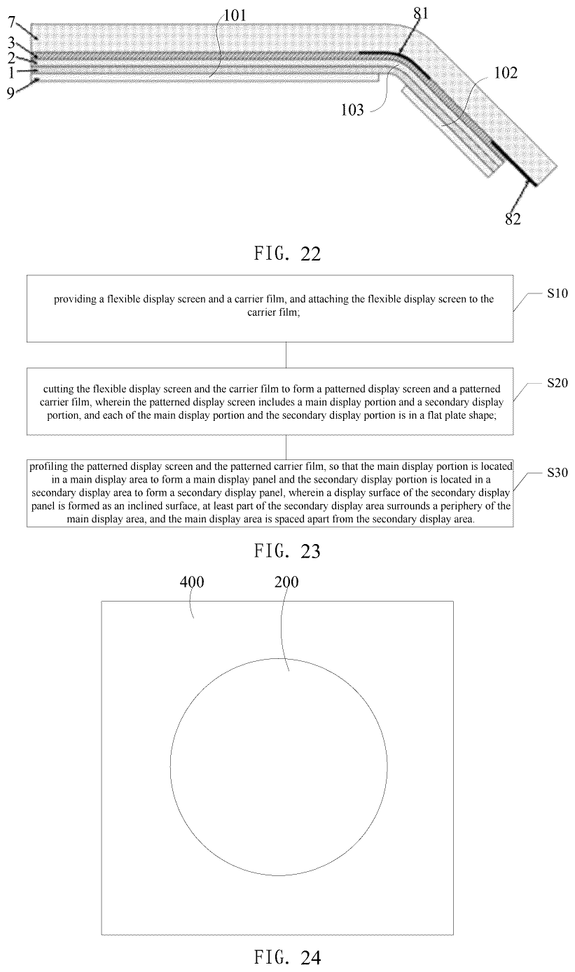

Referring to FIG. 22, the connection portion 103 connected between the main display panel 101 and the secondary display panel 102 may not be provided with the back functional layer 9, thereby reducing the strength of the connection portion 103, making the connection portion 103 more flexible, and facilitating bending of the connection portion 103.

In addition, since an electrical connection between the main display panel 101 and the secondary display panel 102 may be achieved through the connection portion 103, it is possible to only provide the driving backplane 21 on the connection portion 103, and the electrical connection between the main display panel 101 and the secondary display panel 102 may be achieved through wires on the driving backplane 21, while other film layers may not be provided.

Based on the same inventive concept, exemplary embodiments of the present disclosure provide a manufacturing method for a display device. Referring to FIG. 23, the manufacturing method may include following steps:
step S10, providing a flexible display screen and a carrier film, and attaching the flexible display screen to the carrier film;
step S20, cutting the flexible display screen and the carrier film to form a patterned display screen and a patterned carrier film, wherein the patterned display screen includes a main display portion and a secondary display portion, and the main display portion and the secondary display portion are each in a flat plate shape;
step S30, profiling the patterned display screen and the patterned carrier film, to form a main display panel by the main display portion in a main display area and form a secondary display panel by the secondary display portion in a secondary display area, wherein a display surface of the secondary display panel is formed as an inclined surface, at least part of the secondary display area surrounds a periphery of the main display area, and the main display area is spaced apart from the secondary display area.

An extension plane of the display surface of the secondary display panel 102 converges at a side of the main display panel 101 away from the secondary display panel 102 to form a virtual vertex or a virtual straight line; and a ratio of a distance between the virtual vertex or the virtual straight line and a display surface of the main display panel 101 to a distance between a center point and a boundary line of the main display panel 101 is greater than or equal to 0.2 and less than or equal to 12.

The manufacturing method for the display device will be exemplified below.

In this exemplary embodiment, a flexible display screen 200 is prepared and formed, and a shape of the flexible display screen 200 matches a shape of the display device. For example, the display device is circular, and the flexible display screen 200 is configured to be circular; the display device is elliptical, and the flexible display screen 200 is configured to be elliptical; and the display device is rectangular, and the flexible display screen 200 is configured to be rectangular. Certainly, the display device and the flexible display screen 200 may also have other shapes, which are not elaborated herein.

The flexible display screen 200 may not be provided with any drive circuit and any light-emitting device at a location that needs to be subsequently cut and removed, and the drive circuit and the light-emitting device may be provided only in an area where the main display panel 101 and the secondary display panel 102 are formed, thereby ensuring connectivity, and avoiding discontinuity of the drive circuit caused by subsequent cutting and removal, which may otherwise make some light-emitting devices unable to emit light normally.

The carrier film 400 is a flexible film, and may be made of a resin material such as polyimide, polycarbonate, polyacrylate, polyetherimide, polyethersulfone, polyethylene terephthalate, and polyethylene naphthalate. The carrier film 400 may be rectangular. A periphery of the carrier film 400 protrudes from the flexible display screen 200, so that a fixture may clamp at the periphery of the carrier film 400.

Referring to FIG. 24, a non-display surface of the flexible display screen 200 is attached to the carrier film 400.

In this exemplary embodiment, a bonding adhesive is coated on a display surface of the flexible display screen 200, and a material of the bonding adhesive may be an OCA optical adhesive, or certainly, may be other transparent adhesive layers.

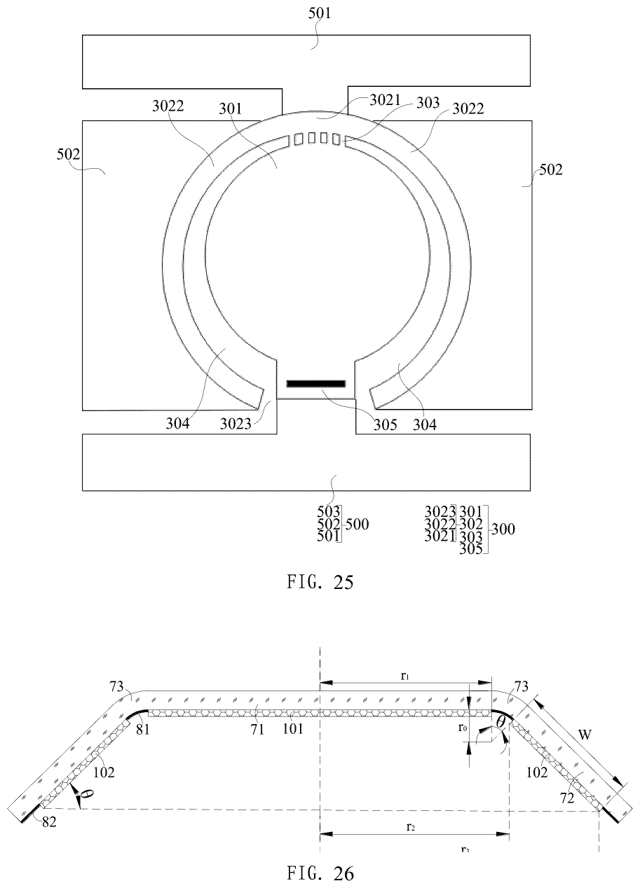

Then, referring to FIG. 25, the flexible display screen 200 and the carrier film 400 are cut simultaneously, and the cutting method may be laser cutting. The flexible display screen 200 forms a patterned display screen 300 by laser cutting, the patterned display screen 300 includes a main display portion 301 and a secondary display portion 302, and both the main display portion 301 and the secondary display portion 302 are planar; and the carrier film 400 forms a patterned carrier film 500 by laser cutting.

Since the main display portion 301 may form the main display panel 101 without need to be deformed, the main display portion 301 has a same structure as the main display panel 101, that is, the main display portion 301 and the main display panel 101 are not only identical in shape but also identical in size. For example, the main display panel 101 may be configured to be circular, and correspondingly, the main display portion 301 may be configured to be circular; the main display panel 101 may be configured to be elliptical, and correspondingly, the main display portion 301 may be configured to be elliptical; the main display panel 101 may be configured to be polygonal, and correspondingly, the main display portion 301 may be configured to be polygonal.

The secondary display portion 302 is configured in a circular ring shape and surrounds a periphery of a part of the main display portion 301.

A ring width throughout the secondary display portion 302 is consistent, the ring width refers to a width of a ring in a radial direction, and in a case where the secondary display portion 302 is configured in the circular ring shape, the ring width is obtained by subtracting a radius of an inner circle from a radius of an outer circle (a radius of an outer circle−a radius of an inner circle). The circular ring is equivalent to a hollow circle, the hollow circle has a small radius (r), the whole circle has a large radius (R), and the radius of the whole circle minus the radius of the hollow circle is the ring width.

Specifically, the secondary display portion 302 may include a first portion 3021 and a second portion 3022 connected to each other, and the first portion 3021 and the second portion 3022 are both configured in a ring shape with the same radius. For example, two second portions 3022 are provided and are symmetrically connected to two opposite sides of the first portion 3021, that is, the second portion 3022, the first portion 3021 and the second portion 3022 are sequentially connected to form the secondary display portion 302. This arrangement can facilitate the design calculation of the secondary display portion 302; and since the secondary display portion 302 is bent to form the secondary display panel 102, this arrangement can reduce bending stress, avoid warping of the secondary display panel 102 and ensure a display effect. Certainly, in other exemplary embodiments of the present disclosure, one second portion 3022 may be provided, and the second portion 3022 is connected to one side of the first portion 3021.

The secondary display portion 302 and the main display portion 301 are connected as a whole. Specifically, the patterned display screen 300 may further include a connection structure 303, the connection structure 303 is connected between the first portion 3021 and the main display portion 301, and the second portion 3022 is spaced apart from the main display portion 301, so that a first gap 304 is provided between the second portion 3022 and the main display portion 301, the connection structure 303 is profiled to form a connection portion 103, and after profiling, the first gap 304 forms a second gap 105.

A width of the first gap 304 in a radial direction increases as a distance from the connection structure 303 increases, that is, the farther away from the connection structure 303 the first gap is, the larger the width of the first gap 304 in the radial direction is.

Referring to FIGS. 8-11, the connection structure 303 is provided with a plurality of via holes 1031, and the via holes 1031 may be rectangular, elliptical, waist circular, cross-shaped, or the like. The connection structure 303 provided with a plurality of via holes 1031 has certain stretchability, to better fit with a connection plate 73 of a cover plate 7. The number of the via holes 1031 may be set as needed.

Referring to FIG. 5, FIG. 6 and FIG. 25, the connection structure 303 may include at least two connection strips 1032, one end of each connection strip 1032 is connected to the main display panel 301, and the opposite other end of each connection strip 1032 is connected to the first portion 3021. The number of the connection strips 1032 may be set as needed. Referring to FIG. 5 and FIG. 25, the connection strips 1032 may be arranged in the shape of linear strips. Likewise, the connection structure 303 arranged in this way has certain stretchability, which can better fit with the connection plate 73 of the cover plate 7.

Referring to FIG. 6 and FIG. 7, each connection strip 1032 is configured in a curved shape; specifically, the connection strip 1032 may be configured in a rectangular curved shape, i.e., a plurality of rectangular notch portions are provided at intervals on two opposite sides of the straight strip. Each connection strip 1032 may be configured in an arc curved shape, i.e., the connection strips 1032 may include one, two or more arc-shaped strips, and two adjacent arc-shaped strips are smoothly connected. The curved connection strip 1032 may also be of a structure in which a rectangular curved strip is connected to an arc curved strip. The curved connection strip 1032 may also have other shapes, which will not be elaborated herein. Likewise, the connection portion 103 arranged in this way has certain stretchability, which can better fit with the connection plate 73 of the cover plate 7.

In this exemplary embodiment, referring to FIG. 25, the secondary display portion 302 has a disconnection structure 3023; specifically, the disconnection structure 3023 is disposed between the two second portions 3022, that is, the secondary display portion 302 is broken by the disconnection structure 3023 to form the two second portions 3022. The disconnection structure 3023 and the connection structure 303 are disposed on two opposite sides of the main display portion 301, to further ensure that the two second portions 3022 are symmetrically disposed, thereby ensuring stress balance of the secondary display portion 302, and ensuring a display and touch effect.

In this exemplary embodiment, referring to FIG. 25, the patterned display screen 300 may further include a first binding structure 305 connected to the main display portion 301; the first binding structure 305 and the connection structure 303 are disposed on two opposite sides of the main display portion 301, that is, the first binding structure 305 is connected to a side of the main display portion 301 away from the connection structure 303; and a part of the first binding structure 305 extends into the disconnection portion 1023. The first binding structure 305 is provided with a plurality of binding pins, the plurality of binding pins may be bound to a display driving chip, and the display driving chip may control the display and touch of the main display portion 301 and the secondary display portion 302.

Referring to FIG. 25, the patterned carrier film 500 may include a main carrier portion (shielded by the main display portion 301, not shown in the figure), a first carrier portion 501, a second carrier portion 502, and a third carrier portion 503. The main carrier portion is configured to carry the main display portion 301; and the main carrier portion has a same shape and size the main display portion 301.

The first carrier portion 501 is connected to the main carrier portion, the first carrier portion 501 is configured to carry the connection structure and the first portion, the first carrier portion 501 protrudes from the first portion, and the protruding first carrier portion 501 is used for clamping by a fixture.

There are two second carrier portions 502 disposed on two opposite sides of the main carrier portion, the second carrier portions 502 are configured to carry two second portions, and the two second carrier portions 502 are symmetrically disposed to ensure uniformity of profiling of the second portions on the two sides. The second carrier portions 502 are spaced apart from the main carrier portion, that is, there is no connection between the second carrier portions 502 and the main carrier portion, which can facilitate profiling of the second portions to form the secondary display panel 102. Each second carrier portion 502 protrudes from the second portion, and the protruding second carrier portion 502 is used for clamping by the fixture.

The third carrier portion 503 is connected to the main carrier portion, and the third carrier portion 503 is configured to carry the first binding structure; and the third carrier portion 503 protrudes from the first binding structure, and the protruding third carrier portion 503 is used for clamping the fixture.

Furthermore, the first carrier portion 501, the second carrier portion 502 and the third carrier portion 503 are spaced apart; that is, the first carrier portion 501 is spaced apart from the second carrier portion 502, and the second carrier portion 502 is spaced apart from the third carrier portion 503, so that each portion may be conveniently profiled.

Furthermore, since the secondary display portion 302 needs to be bent and deformed to form the secondary display panel 102, parameters of the secondary display portion 302 need to be calculated and determined.

Individual parameters of the patterned display screen 300 in a planar state are determined according to parameters of the flexible display panel 100 in a three-dimensional state.

An example where the main display portion 301 is configured in a circular shape and the secondary display portion 302 configured in a sector ring shape will be illustrated below. Referring to FIGS. 26-28, a calculation formula for determining individual parameters of the patterned display screen 300 according to the flexible display panel 100 includes:

$$\{ \begin{matrix}{L}_{out} = {r}_{3} * ( 360 ° - α ) \\ {L}_{in} = {r}_{2} * ( 360 ° - α )\end{matrix} ;$$

$$\{ \begin{matrix}{L}_{out} = R * ( 360 ° - β ) \\ {L}_{in} = ( R - W ) * ( 360 ° - β )\end{matrix} ;$$

$${r}_{3} = {r}_{1} + {r}_{0} * Sin θ + {W}_{1} * cos θ ;$$

$$R = {r}_{3} / cos θ ;$$

$${L}_{0} = {r}_{0} * θ ;$$

$$D = R - W - {L}_{0} - {r}_{1} ;$$

$$360 ° - β = {L}_{out} / R .$$

In the formula, r₂ is a radius of an edge line of the secondary display panel 102 close to the main display panel 101 in the three-dimensional state; r₃ is a radius of an edge line of the secondary display panel 102 away from the main display panel 101 in the three-dimensional state; r₀ is a radius of curvature of the connection portion 103 in the three-dimensional state; 0 is an inclination angle of the secondary display panel 102 in the three-dimensional state, i.e., 0 is an angle between the secondary display panel 102 and a first reference plane in the three-dimensional state, and the first reference plane is parallel to the display surface of the main display panel 101; and α is a central angle corresponding to the disconnection portion 1023 in the three-dimensional state. These parameters in the three-dimensional state are all known parameters.

R is a radius of an edge line of the secondary display portion 302 away from the main display portion 301 in the planar state; β is a central angle corresponding to the disconnection structure 3023 in the planar state; D is a distance between a center of the secondary display portion 302 and a center of the main display portion 301 in the planar state; and L₀ is a width of the connection structure 303 in a radial direction in the planar state. These parameters in the planar state are all parameters to be solved.

r₁ is a radius of the main display panel 101; W is a width of the secondary display panel 102 in a radial direction; Lₒᵤₜ is a length of an edge line of the secondary display panel 102 away from the main display panel 101; and Lᵢₙ is a length of an edge line of the secondary display panel 102 close to the main display panel 101. These parameters do not change when the flexible display panel 100 is profiled and formed into the three-dimensional state from the planar state, so these parameters are identical in the three-dimensional state and in the planar state, and these parameters are all known parameters.

Consequently, the parameters R, D, β, L₀ to be solved may be calculated according to the following formula:

$$\{ \begin{matrix}{L}_{out} = R * ( 360 ° - β ) \\ {L}_{in} = ( R - W ) * ( 360 ° - β )\end{matrix} ;$$

$${L}_{0} = {r}_{0} * θ ;$$

$$D = R - W - {L}_{0} - {r}_{1} .$$

Certainly, other formulas including the to-be-solved parameters may also be selected from the above formulas for calculation.

As shown in Table 1, five embodiments are listed, and unknown parameters in the planar state are obtained through calculation based on some known parameters and some known invariant parameters in the three-dimensional state.

TABLE 1

| | | | | | Known invariant | | | | | |
|---|---|---|---|---|---|---|---|---|---|---|
| | Known parameters in | | | | parameters in the | | | | | |
| | the three-dimensional | | | | three-dimensional | | Unknown parameters in | | | |
| | state | | | | state | | the planar state | | | |
| | r₁ | r₃ | r₀ | θ | Lₒᵤₜ | W | R | D | 360°-β | L₀ |
| Embodiment 1 | 20 | 30 | 1 | 30 | 109 | 5 | 34.641 | 9.117 | 180.285 | 0.524 |
| Embodiment 2 | 25 | 30 | 0.9 | 25 | 150 | 5 | 33.101 | 2.709 | 259.638 | 0.393 |
| Embodiment 3 | 30 | 40 | 0.75 | 20 | 200 | 8 | 42.567 | 4.305 | 269.202 | 0.262 |
| Embodiment 4 | 15 | 30 | 1.5 | 15 | 100 | 10 | 31.058 | 5.666 | 184.478 | 0.393 |
| Embodiment 5 | 50 | 80 | 2 | 40 | 500 | 20 | 104.433 | 33.036 | 274.319 | 1.396 |

Referring to FIG. 25 and FIG. 26, in a case where the main display portion 301 is configured as a rounded rectangle, the secondary display portion 302 may include a first sub-display portion 3023 and a second sub-display portion 3024; the first sub-display portion 3023 is configured in a rectangular shape; the second sub-display portion 3024 is configured in a sector ring shape, and a central angle corresponding to the second sub-display portion 3024 is greater than 0° and less than 90°; for example, the central angle corresponding to the second sub-display portion 3024 may be 5°, 10°, 15°, 20°, 25°, 30°, 35°, 40°, 45°, 50°, 55°, 60°, 65°, 70°, 75°, 80°, 83°, 88°, etc. This angle is related to an angle between the second sub-display panel 1025 and the first reference plane; generally, the larger the angle between the second sub-display panel 1025 and the first reference plane is, the smaller the central angle corresponding to the second sub-display portion 3024 is; and conversely, the smaller the angle between the second sub-display panel 1025 and the first reference plane is, the larger the central angle corresponding to the second sub-display portion 3024 is.

It should be noted that although the various steps of the manufacturing method for the display device according to the present disclosure are described in a particular order in the figures, it is not required or implied that the steps must be performed in the particular order, or all the illustrated steps must be performed to achieve the desired result. Additionally or alternatively, some steps may be omitted, or multiple steps may be combined into one step to be performed, and/or one step is decomposed into multiple steps to be performed.

Other embodiments of the disclosure will be apparent to those skilled in the art from consideration of the specification and practice of the disclosure disclosed herein. This application is intended to cover any variations, uses, or adaptations of the disclosure following, in general, the principles of the disclosure and including such departures from the present disclosure as come within known or customary practice in the art to which the disclosure pertains. It is intended that the specification and examples be considered as exemplary only.

1. A display device, having a main display area and a secondary display area at least partially surrounding a periphery of the main display area, the main display area being spaced apart from the secondary display area, wherein the display device comprises:
a flexible display panel, comprising:
a main display panel disposed in the main display area; and
a secondary display panel disposed in the secondary display area,
wherein a display surface of the secondary display panel is configured as an inclined surface; an extension plane of the display surface of the secondary display panel converges at a side of the main display panel away from the secondary display panel to form a virtual vertex or a virtual straight line; and a ratio of a distance between the virtual vertex or the virtual straight line and a display surface of the main display panel to a distance between a center point and a boundary line of the main display panel is greater than or equal to 0.2 and less than or equal to 12.

2. The display device according to claim 1, wherein the secondary display panel comprises a first display portion and a second display portion connected to each other; the flexible display panel further comprises:
a connection portion connected between the first display portion and the main display panel; and the second display portion is spaced apart from the main display panel.

3. The display device according to claim 2, wherein the connection portion is provided with a plurality of via holes; or
the connection portion comprises at least two connection strips, an end of each of the connection strips is connected to the main display panel, and an opposite end of each of the connection strips is connected to the first display portion.

4-5. (canceled)

6. The display device according to claim 2, wherein the secondary display panel has a disconnection portion, and the disconnection portion and the connection portion are disposed on two opposite sides of the main display panel.

7. The display device according to claim 6, wherein the flexible display panel further comprises:
a first binding portion connected to the main display panel, the first binding portion extending to the disconnection portion, and the first binding portion being provided with a plurality of binding pins.

8. The display device according to claim 6, further comprising:
a cover plate disposed on a display surface of the flexible display panel,
wherein the cover plate comprises:
a main plate disposed in the main display area; and
an edge plate disposed in the secondary display area, the edge plate being connected to a periphery of the main plate, and a surface of the edge plate close to the flexible display panel being attached to the display surface of the secondary display panel.

9-10. (canceled)

11. The display device according to claim 8, wherein the cover plate further comprises:
a connection plate connected between the main plate and the edge plate, the connection plate having a positive Gaussian curvature, and the connection portion being attached to the connection plate.

12. The display device according to claim 8, further comprising:
a first shielding portion disposed on a side of the cover plate close to the flexible display panel, and the first shielding portion being located between the main display area and the secondary display area.

13. The display device according to claim 12, further comprising:
a second shielding portion disposed on the side of the cover plate close to the flexible display panel, and the second shielding portion being located on a side of the secondary display area away from the main display area.

14. The display device according to claim 13, further comprising:
a third shielding portion disposed on the side of the cover plate close to the flexible display panel, connected between the first shielding portion and the second shielding portion, and at least covering the disconnection portion.

15. (canceled)

16. The display device according to claim 1, wherein a length and a width of a cross section of the display surface of the secondary display panel on a first reference plane are increased as a distance from the main display panel in a second direction increases, wherein the first reference plane is parallel to the display surface of the main display panel, and the second direction is perpendicular to the first reference plane.

17-18. (canceled)

19. The display device according to claim 16, wherein the main display panel is configured as a rounded rectangle; and the secondary display panel comprises:
a first sub-display panel configured in a rectangular shape; and
a second sub-display panel configured in a partially conical ring shape.

20. The display device according to claim 19, wherein four first sub-display panels are provided, four second sub-display panels are provided, and each second sub-display panels is connected between two adjacent first sub-display panels; and two first sub-display panels on two opposite sides of the main display panel have a same angle relative to the first reference plane; extension planes of the two first sub-display panels on the two opposite sides of the main display panel converge to form a virtual straight line; extension planes of the four first sub-display panels converge to form two virtual straight lines, and the two virtual straight lines are perpendicular to each other.

21. A manufacturing method for a display device, comprising:
providing a flexible display screen and a carrier film, and attaching the flexible display screen to the carrier film;
cutting the flexible display screen and the carrier film to form a patterned display screen and a patterned carrier film, wherein the patterned display screen comprises a main display portion and a secondary display portion, and each of the main display portion and the secondary display portion is in a flat plate shape; and
profiling the patterned display screen and the patterned carrier film, so that the main display portion is located in a main display area to form a main display panel, and the secondary display portion is located in a secondary display area to form a secondary display panel, wherein a display surface of the secondary display panel is formed as an inclined surface, at least part of the secondary display area surrounds a periphery of the main display area, and the main display area is spaced apart from the secondary display area,
wherein an extension plane of the display surface of the secondary display panel converges at a side of the main display panel away from the secondary display panel to form a virtual vertex or a virtual straight line; and a ratio of a distance between the virtual vertex or the virtual straight line and a display surface of the main display panel to a distance between a center point and a boundary line of the main display panel is greater than or equal to 0.2 and less than or equal to 12.

22. The manufacturing method according to claim 21, wherein the secondary display portion comprises a first portion and a second portion connected to each other; and the patterned display screen further comprises:
a connection structure connected between the first portion and the main display portion, wherein a first gap is provided between the second portion and the main display portion, and the connection structure is profiled to form a connection portion.

23-24. (canceled)

25. The manufacturing method according to claim 22, wherein the patterned display screen further comprises:
a first binding structure connected to the main display panel, the first binding structure extending into a disconnection structure, the first binding structure being provided with a plurality of binding pins, and the first binding structure being profiled to form a first binding portion.

26. The manufacturing method according to claim 25, wherein the patterned carrier film comprises:
a main carrier portion configured to carry the main display portion;
a first carrier portion connected to the main carrier portion and configured to carry the connection structure and the first portion;
two second carrier portions disposed on two opposite sides of the main carrier portion, the second carrier portions being spaced apart from the main carrier portion, and the second carrier portions being configured to carry the second portion; and
a third carrier portion connected to the main carrier portion and configured to carry the first binding structure,
wherein the first carrier portion, the second carrier portion, and the third carrier portion are spaced apart from each other.

27. The manufacturing method according to claim 25, wherein the main display portion is configured in a circular shape, and the secondary display portion is configured in a sector ring shape; before cutting the flexible display screen and the carrier film, the manufacturing method further comprises:
calculating a parameter of the patterned display screen by using a calculation formula, where the calculation formula comprises:
$$\{ \begin{matrix}{L}_{out} = R * ( 360 ° - β ) \\ {L}_{in} = ( R - W ) * ( 360 ° - β )\end{matrix} ;$$
$${L}_{0} = {r}_{0} * θ ;$$
$$D = R - W - {L}_{0} - {r}_{1} ;$$
$${r}_{3} = {r}_{1} + {r}_{0} * Sin θ + {W}_{1} * cos θ ;$$
$$R = {r}_{3} / cos θ ;$$
wherein R is a radius of an edge line of the secondary display portion away from the main display portion in a planar state; β is a central angle corresponding to the disconnection structure in the planar state; D is a distance between a center of the secondary display portion and a center of the main display portion in the planar state; L₀ is a width of the connection structure in a radial direction in the planar state; Lₒᵤₜ is a length of an edge line of the secondary display panel away from the main display panel; Lᵢₙ is a length of an edge line of the secondary display panel close to the main display panel; r₀ is a radius of a curvature of the connection portion in a three-dimensional state; r₁ is a radius of the main display panel; W is a width of the secondary display panel in the radial direction; and θ is an angle between the secondary display panel and a first reference plane in the three-dimensional state.

28. The manufacturing method according to claim 21, wherein the main display portion is configured as a rounded rectangle; and the secondary display portion comprises:
a first sub-display portion configured in a rectangular shape; and
a second sub-display portion configured in a sector ring shape, a central angle corresponding to the second sub-display portion being greater than 0° and less than 90°.

29. The manufacturing method according to claim 21, further comprising:
providing a cover plate, and attaching the cover plate to a display surface of the patterned display screen after being profiled.
